(19) United States
(12) Patent Application Publication
(10) Pub. No.: US 2026/0361320 A1
(43) Pub. Date: Nov. 12, 2026

(54) HIERARCHICAL SHIFTING CIRCUIT FOR COMPUTATION BASED ON TWO STAGE CIRCULANT PARITY CHECK MATRIX

(71) Applicant: Silicon Motion, Inc., Hsinchu County (TW)

(72) Inventors: Duen-Yih Teng, Hsinchu County (TW); Shiuan-Hao Kuo, Hsinchu County (TW)

(73) Assignee: Silicon Motion, Inc., Hsinchu County (TW)

(21) Appl. No.: 19/200,696

(22) Filed: May 7, 2025

(51) Int. Cl. H03M 13/11; H03M 13/00

(52) U.S. Cl. CPC H03M 13/1174; H03M 13/616

(57) ABSTRACT

A shifting circuit configured for performing data shifting operations associated with computation based on a two-stage circulant parity-check matrix, includes: an up shifter and at least one first barrel shifter. The up shifter is configured to perform a coarse-grained circular shift operation on input data to generate intermediate shifted data. The at least one first barrel shifter is configured to receive a first portion of the intermediate shifted data and perform a fine-grained circular shift operation on the first portion of the intermediate shifted data to generate first output shifted data.

### BACKGROUND OF THE INVENTION

### 1. Field of the Invention

The present invention relates to coding systems, and more particularly to a hierarchical shifting circuit for computation based on two-stage circulant parity-check matrix.

### 2. Description of the Prior Art

Low-Density Parity-Check (LDPC) codes are widely recognized for their near-capacity error correction performance and efficient iterative decoding algorithms. Due to their strong error resilience and scalability, LDPC codes have been adopted in numerous high-throughput communication and storage standards, including 5G NR, Wi-Fi and flash memory systems.

Quasi-Cyclic LDPC (QC-LDPC) codes are a subclass of LDPC codes where its parity-check matrix is composed of circulant permutation matrices (CPMs) and zero matrices. The quasi-cyclic nature of QC-LDPC enables hardware-friendly implementations by allowing regular and modular encoding and decoding operations, significantly reducing memory and routing complexity in circuit design. The inherent structure of QC-LDPC codes makes them well-suited for implementation using barrel shifters, which can efficiently perform circular shift operations required during encoding and decoding processes. However, conventional barrel shifters are typically optimized for data widths that are powers of two. When applied to data with non-power-of-two bit widths, this leads to significant waste of circuit area and manufacture cost due to resource underutilization.

Accordingly, there is a need for an improved shifting circuit that can efficiently support QC-LDPC encoding and decoding operations while minimizing circuit area and manufacture cost, particularly in systems where the data width does not conform to a powers-of-two configuration.

### SUMMARY OF THE INVENTION

The present invention provides hierarchical shifting circuit architecture for efficiently performing circular shift operations on input data of arbitrary bit widths using barrel shifters having powers-of-two input widths. The hierarchical structure comprises an up shifter for performing coarse-grained circular shift and a barrel shifter having powers-of-two input widths for performing fine-grained circular shift. The up shifter performs segment-wise circular shift on input data to rearrange segments of the input data, while the barrel shifter performs bit-wise circular shift within each segment.

To enable the application of hierarchical structure across a wide range of QC-LDPC coding systems, the present invention further introduces a two-stage circulant parity-check matrix structure. The proposed two-stage circulant parity-check matrix structure is specifically designed to align with operational characteristics of the hierarchical shifting circuit, ensuring that both encoding and decoding processes in QC-LDPC coding systems can be implemented using the same hardware-friendly and economical hierarchical shifting circuit.

According to one embodiment, a shifting circuit configured for performing data shifting operations associated with computation based on a two-stage circulant parity-check matrix is provided. The shifting circuit comprises: an up shifter and at least one first barrel shifter. The up shifter is configured to perform a coarse-grained circular shift operation on input data to generate intermediate shifted data. The at least one first barrel shifter is configured to receive a first portion of the intermediate shifted data and perform a fine-grained circular shift operation on the first portion of the intermediate shifted data to generate first output shifted data.

According to one embodiment, a memory controller for use in a flash memory is provided. The memory controller comprises a shifting circuit configured to perform data shifting operations associated with computation based on a two-stage circulant parity-check matrix. The shifting circuit comprises: an up shifter and at least one first barrel shifter. The up shifter is configured to perform a coarse-grained circular shift operation on input data to generate intermediate shifted data. The at least one first barrel shifter is configured to receive a first portion of the intermediate shifted data and perform a fine-grained circular shift operation on the first portion of the intermediate shifted data to generate first output shifted data.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a schematic diagram a data storage device and an electronic device according to one embodiment of the present invention.

FIG. 2 illustrates decomposition of a two-stage circulant parity-check matrix according to one embodiment of the present invention.

FIG. 3 illustrates comparison between abstractive representation of a conventional parity-check matrix and a two-stage circulant parity-check matrix according to one embodiment of the present invention.

FIG. 4 illustrates a schematic diagram of a shifting circuit according to one embodiment of the present invention.

FIG. 5 illustrates a schematic diagram of a partial shifting circuit according to one embodiment of the present invention.

### DETAILED DESCRIPTION

Embodiments will be described in detail with reference to the accompanying drawings. The inventive concept, however, may be embodied in various different forms, and should not be construed as being limited only to the illustrated embodiments. Rather, these embodiments are provided as examples so that this disclosure will be thorough and complete, and will fully convey the concept of the inventive concept to those skilled in the art. Accordingly, known processes, elements, and techniques are not described with respect to some of the embodiments of the inventive concept. Unless otherwise noted, like reference numerals denote like elements throughout the attached drawings and written description, and thus descriptions will not be repeated. In the drawings, the sizes and relative sizes of layers and regions may be exaggerated for clarity.

Reference throughout this specification to “one embodiment” or “an embodiment” means that a particular feature, structure or characteristic described in connection with the embodiment or example is included in at least one embodiment of the present embodiments. Thus, appearances of the phrases “in one embodiment” or “in an embodiment” in various places throughout this specification are not necessarily all referring to the same embodiment. Furthermore, the particular features, structures or characteristics may be combined in any suitable combinations and/or sub-combinations in one or more embodiments.

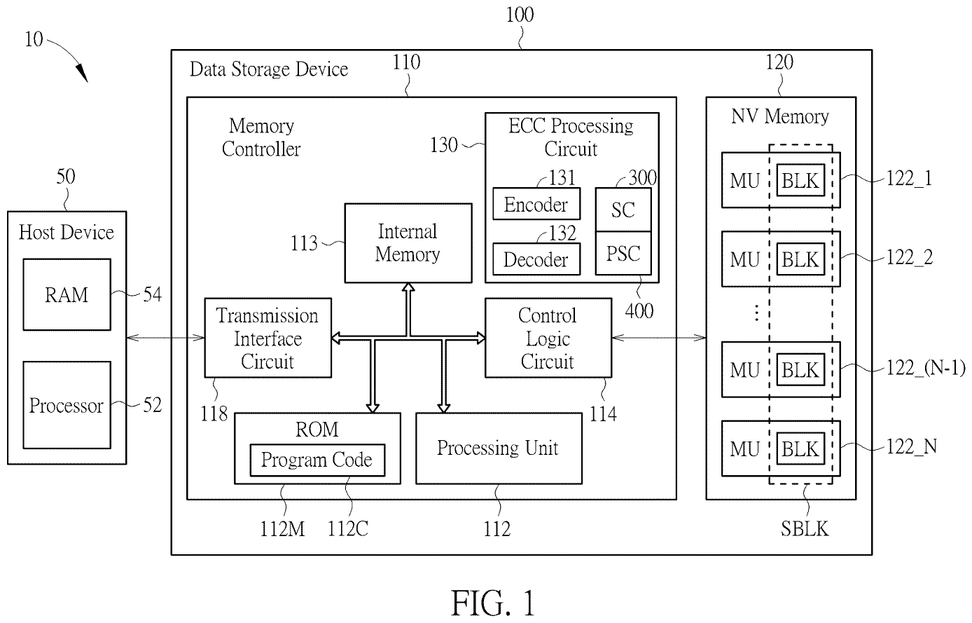

FIG. 1 is a schematic diagram illustrating an electronic device and a data storage device according to one embodiment of the present invention. As illustrated an electronic device 10 comprises a host device 50 and a data storage device 100. The host device 50 may comprise: at least one processor 52 configured to control operations of the host device 50, and a random access memory 54 configured to store data and information required by the processor 52. Examples of the host device 50 may include, but are not limited to: a smartphone, a tablet computer, a wearable device, a personal computer (such as, a desktop computer or a laptop computer), an imaging device (such as, a digital still camera or a video camera), a game console, a car navigation system, a printer, a scanner, or a server system. Examples of the data storage device 100 may include, but are not limited to: a portable memory device (such as a memory card conforming to SD/MMC, CF, MS, XD, or UFS specifications), a solid-state drive (SSD), and various embedded storage devices (such as an embedded storage device conforming to UFS or EMMC specifications).

According to various embodiments, the data storage device 100 may comprise a memory controller 110 and may further comprise a non-volatile (NV) memory 120. The NV memory 120 may comprise one or more NV memory elements, such as a plurality of NV memory elements (MU) 122_1-122_N. For example, the NV memory 120 may be a NAND flash memory, and the NV memory elements 122_1-122_N may be a plurality of NAND flash memory packages or a plurality of NAND flash memory dies, respectively, but the present invention is not limited thereto.

In some embodiments, the NV memory 120 may include a plurality of memory blocks BLK, which may be grouped into a plurality of superblocks SBLK. The memory block BLK may refer to a physical block and includes a plurality of memory cells. The superblock SBLK may be a unit of a logical memory region required for the memory controller 110 to manage the NV memory, where a composition of a superblock SBLK can span across NV memory chips 122_1-122_N. The memory block BLK may be implemented as a memory cell array in which a plurality of memory cells form a two-dimensional (2D) or three-dimensional (3D) array structure. The plurality of memory cells may be single-level cells programmed with one bit or multi-level cells (e.g., double-level cells, triple-level cells or quadruple-level cells) programmed with two bits or more. Moreover, the memory block BLK may include a plurality of pages, where memory cells connected to a same word line may constitute a page. For example, the memory block BLK may be a unit of an erase operation, and the page may be a unit of program and read operations.

In some embodiments, each of NV memory units 122_1-122_N is equipped with control circuitry for executing memory operation commands issued by the memory controller 110. Each of NV memory dies 122_1-122_N may include multiple planes, where each plane may have multiple blocks composed of memory cells, along with associated row and column control circuitry. Through multi-plane operation commands, various memory operations can be applied parallel on different planes to perform multi-plane reading, writing or erasing operations.

The memory controller 110 may comprise a processing unit 112, a read-only memory (ROM) 112M, an internal memory 113, a transmission interface circuit 118, an error checking and correction (ECC) processing circuit 130. At least one portion of these circuits and components may be coupled to one another through a bus. The internal memory 113 can be implemented by one or more RAM devices. For example, the internal memory 113 may comprise a static RAM (SRAM) and/or a dynamic RAM (DRAM). The internal memory 113 could be configured to provide internal storage space for the memory controller 110, for example, temporarily storing information, such as data, addresses, commands, mapping information, and/or variables/parameters. In some embodiments, the memory controller 110 may not include DRAM. Instead, the memory controller 110 may rely on host memory buffer (HMB) technology. With the HMB technology, the memory controller 110 could utilize the RAM 54 (such as DRAM) of the host device 50, as a whole, a part or an extension of the internal memory 113, thereby improving read and write performance of the data storage device 100.

In addition, the ROM 112M in this embodiment is configured to store program code 112C, and the microprocessor 112 is configured to execute the program code 112C, thereby controlling access to the NV memory 120. The program code 112C may include one or more program modules, such as boot loader code. When the data storage device 100 obtains power from the host device 50, the processing unit 112 may execute an initialization process of the data storage device 100 by executing the program code 112C. During the initialization process, the microprocessor 112 may load a set of in-system programming (ISP) codes (not shown in FIG. 1) from the NV memory 120. The microprocessor 112 can execute the ISP codes so that the data storage device 100 can be operable to perform various functions. According to one embodiment of the present invention, the set of ISP codes may include, but are not limited to: one or more program modules associated with memory access (e.g., reading, writing, and erasing), such as, a read operation module, a lookup table module, a wear leveling module, a read refresh module, a read reclaim module, and a garbage collection module, an sudden power-off recovery(SPOR) module, which are provided to perform corresponding reading, lookup table querying, wear leveling, read refreshing, read reclaiming, garbage collection, SPOR and other operations.

The memory controller 110 controls reading, writing, and erasing of the NV memory 120 through a flash control circuit 150. In addition, the memory controller 110 could perform writing of data based on host commands from the host device 50 and writing of valid data which is read from the NV memory 120 by a garbage collection and/or a wear-leveling operation concurrently. The transmission interface circuit 118 may conform to a specific communications specification, such as, Universal Serial Bus (USB) specification, Secure Digital (SD) interface, Ultra High Speed-I (UHS-I) interface, Ultra High Speed-II (UHS-II), CompactFlash (CF) interface, Multimedia card (MMC) interface, embedded Multimedia Card (eMMC) specification, Advanced Technology Attachment (ATA), Serial Advanced Technology Attachment (SATA), Parallel Advanced Technology Attachment (PATA), Peripheral Component Interconnect Express (PCI-E), and Universal Flash Storage (UFS) specification, and may perform communications with the host device 50 according to the specific communications specification.

Typically, the host device 50 may indirectly access the memory device 100, through transmitting host commands and corresponding logic addresses to the memory controller 110. The memory controller 110 receives the host commands and the logic addresses, and translates the host commands to memory operation commands, and further controls the NV memory 120 with the memory operation commands to perform read, program or erase operations upon memory cells or data pages having physical addresses within the NV memory 120.

In one embodiment, the ECC processing circuit 130 comprises an encoder 131 and a decoder 132. Both encoding and decoding operations are based on a two-stage circulant parity-check matrix for generating or validating codewords. Specifically, the encoder 131 utilizes a generator matrix derived from the two-stage circulant parity-check matrix to encode user data received from the host device 50, and outputs a corresponding codeword to be stored in the NV memory 120. On other hand, the decoder 132 uses the two-stage circulant parity-check matrix to verify the integrity of a codeword retrieved from the NV memory 120 and performs bit error correction when necessary. According to various embodiments, the encoder 131 and decoder 132 may be Quasi-Cyclic Low-Density Parity-Check (QC-LDPC) encoder and decoder configured to perform QC-LDPC encoding and decoding.

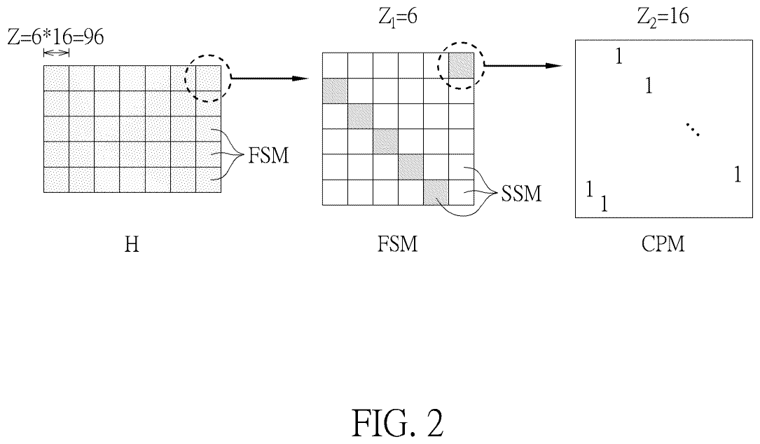

Referring to FIG. 2, a parity-check matrix H utilized in the ECC operations of the encoder 131 and decoder 132 may adopt a two-stage circulant structure. In the illustrated embodiment, the parity-check matrix H can be decomposed into a 5×7 array of first-level sub-matrices FSM, each being a 96×96 matrix (Z=96). Each of first-level sub-matrices FSM can be further decomposed into a 6×6 array of second-level sub-matrices SSM, where each of second-level sub-matrices SSM is a 16×16 matrix (Z₂=16). Although specific matrix dimensions and decompositions are shown in FIG. 2 for illustrative clarity, the present invention is not limited thereto.

As illustrated by FIG. 2, one or more of the first-level sub-matrices FSM are block-circulant matrices. In a block-circulant first-level sub-matrix FSM, each row or column contains only one non-zero second-level sub-matrix SSM with all the other second-level sub-matrices SSM being zero matrices. Moreover, the non-zero second-level sub-matrix SSM in each row or column is a circulant permutation matrix (CPM). As illustrated, each subsequent row of the block-circulant first-level sub-matrix FSM is a circular shift (e.g., one-position right circular shift) of a previous row, thereby forming a regular cyclic pattern across the whole matrix. The circulant permutation matrix is a square binary matrix in which each row is a one-position right circular shift of the row above it. A circulant permutation matrix contains exactly one entry of logical “1” in each row and each column, with all other entries being logic “0”. In view of the above, the parity-check matrix H exhibits a two-stage circulant structure, comprising an outer level of block-wise circulant organization and an inner level of element-wise circulant permutation.

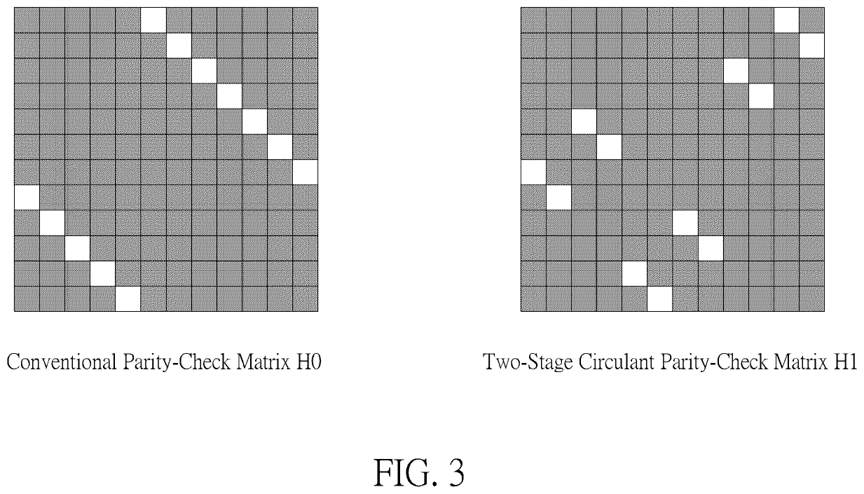

FIG. 3 illustrates an abstract comparison between a two-stage circulant parity-check matrix H1 and a conventional QC-LDPC parity-check matrix H0, according to one embodiment of the present invention. As shown, the conventional QC-LDPC parity-check matrix H0 exhibits global circulant properties, in which the non-zero sub-matrices (or non-zero elements) follow a uniform cyclic pattern across the whole matrix. In contrast, the two-stage circulant parity-check matrix H1 exhibits localized circulant properties. Specifically, cyclic patterns exist within certain sub-regions of the whole matrix. In FIG. 3, white squares represent non-zero submatrices (e.g., circulant permutation matrices) or non-zero elements, and black squares represent zero sub-matrices or zeros.

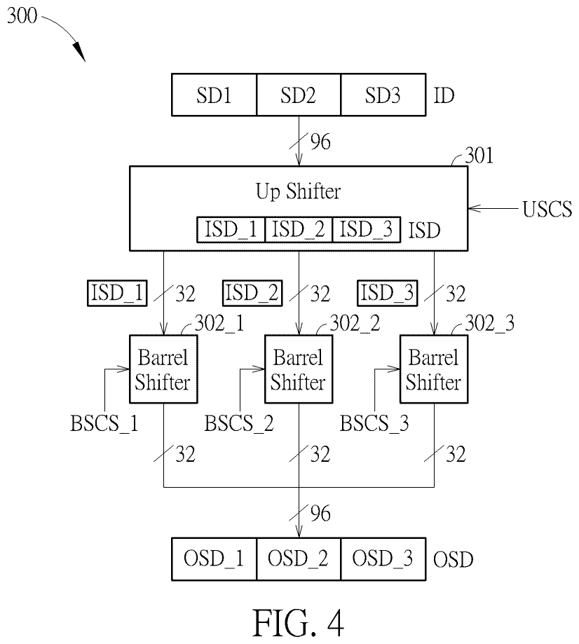

Please refer to FIG. 4, which illustrates a schematic diagram of a hierarchical shifting circuit according to one embodiment of the present invention. A shifting circuit (SC) 300 illustrated by FIG. 4 can implemented in the encoder 131 or the decoder 132 to perform data shift operations associated with computations based on the two-stage circulant parity-check matrix described above.

As illustrated, the shifting circuit 300 comprises an up shifter 301 and a plurality of barrel shifters 302_1-302_3. The number of barrel shifters may vary depending on the design requirements of the encoder 131 or decoder 132, and/or the structure of the corresponding two-stage parity-check matrix.

The up shifter 301 is configured to perform a coarse-grained circular shift operation on input data ID to generate intermediate shifted data ISD. The barrel shifters 302_1-302_3 are configured to respectively receive a respective portion of the intermediate shifted data ISD and perform a fine-grained circular shift operation on the respective portion of the intermediate shifted data ISD, generating a portion of output shifted data. For example, the barrel shifter 302_1 is configured to receive a first portion ISD_1 of the intermediate shifted data ISD and perform the fine-grained circular shift operation on the first portion ISD_1 of the intermediate shifted data ISD to generate a first portion OSD_1 of output shifted data OSD. The barrel shifter 302_2 is configured to receive a second portion ISD_2 of the intermediate shifted data ISD and perform the fine-grained circular shift operation on the second portion ISD_2 of the intermediate shifted data ISD to generate a second portion OSD_2 of output shifted data OSD. The barrel shifter 302_3 is configured to receive a third portion ISD_3 of the intermediate shifted data ISD and perform the fine-grained circular shift operation on the third portion ISD_3 of the intermediate shifted data ISD to generate a third portion OSD_3 of output shifted data OSD.

By hierarchically separating the shift operation into coarse and fine stages, the shifting circuit 300 enables efficient implementation of shift patterns aligned with the structure of the two-stage circulant parity-check matrix, while optimizing hardware usage, particularly when input data widths are not powers of two.

Specifically, the up shifter 301 is configured to perform a segment-wise circular shift operation on the input data ID (e.g., 96-bit wide data). For example, the input data ID can be divided into a first segment SD1, a second segment SD2 and a third segment SD3, wherein each segment contains multiple bits (e.g., 32-bit wide data) of the input data ID. Under control of an up shift control signal USCS, the up shifter 301 is configured to perform the segment-wise circular shift operation, thereby to rotate or circular shift the first segment SD1, a second segment SD2 and a third segment SD3, in a segment-wise manner (i.e., serving a 32-bit segment as a whole) to generate the intermediate shifted data ISD.

In addition, the barrel shifters 302_1-302_3 are configured to respectively perform a bit-wise circular shift operation on the respective portions of the intermediate shifted data ISD. For example, the barrel shifter 302_1 is configured to perform a bit-wise circular shift on the first portion ISD_1 (e.g. 32-bit wide data) of the intermediate shifted data ISD according to a barrel shift control signal BSCS_1 thereby to rotate or circular shift bits within the first portion ISD_1, in a bit-wise manner to generate the first portion OSD_1 (e.g. 32-bit wide data) of output shifted data OSD. The barrel shifter 302_2 is configured to perform a bit-wise circular shift on the second portion ISD_2 of the intermediate shifted data ISD according to a barrel shift control signal BSCS_2 thereby to rotate or circular shift bits within the second portion ISD_2, in a bit-wise manner to generate the second portion OSD_2 of output shifted data OSD. The barrel shifter 302_3 is configured to perform a bit-wise circular shift on the third portion ISD_3 of the intermediate shifted data ISD according to a barrel shift control signal BSCS_3 thereby to rotate or circular shift bits within the third portion ISD_3, in a bit-wise manner to generate the third portion OSD_3 of output shifted data OSD.

Under the hierarchical structure of the shifting circuit 300, hardware implementation is mostly based on the barrel shifters 302_1-302_3 whose utilization is optimized for data widths that are powers of two. For example, even when the overall data block processed by the encoder 131 or decoder 132 is not a power of two (e.g., 96-bit data block in the illustrated embodiment), the hierarchical structure of the shifting circuit 300 allows each barrel shifter 302_1-302_3 to still operate on 32-bit segments. Please note that although the figures show specific data processing bit widths, this is not a limitation of the invention.

It is widely recognized that digital circuits designed with power-of-two data widths offer numerous advantages, including simplified circuitry complexity, and compatibility with memory and register structures. By structuring the shift operation into a coarse-grained and fine-grained stage, the present invention enables practical implementation of circular shifts on non-power-of-two data widths using hardware-efficient, power-of-two-aligned barrel shifter modules.

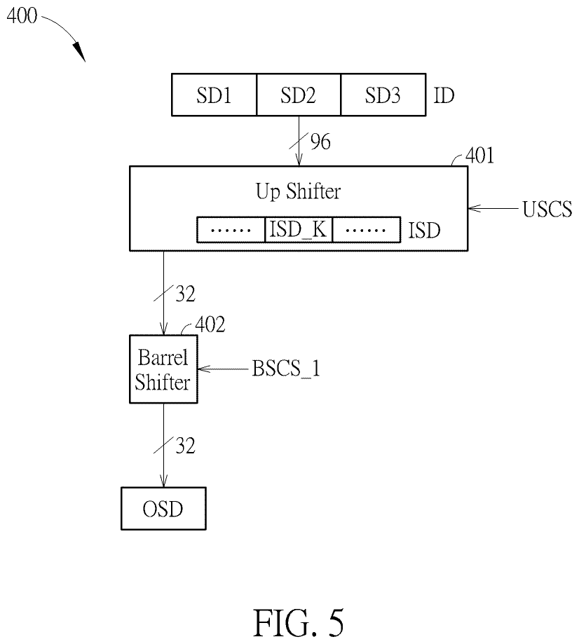

Please refer to FIG. 5, which illustrates a schematic diagram of a hierarchical shifting circuit according to one embodiment of the present invention. A partial shifting circuit (PSC) 400 illustrated by FIG. 5 can be implemented in the encoder 131 or the decoder 132 for performing data shifting operations associated with computation based on the above-mentioned two-stage circulant parity-check matrix. Compared to the shifting circuit 300 of FIG. 4, the shifting circuit 400 is optimized for partial output.

As illustrated, the shifting circuit 400 comprises an up shifter 401 and a barrel shifter 402. Similarly, the up shifter 401 is configured to perform a coarse-grained circular shift operation on input data ID to generate intermediate shifted data ISD. The barrel shifter 402 is configured to receive a specific portion of the intermediate shifted data ISD and perform a fine-grained circular shift operation on the specific portion of the intermediate shifted data ISD to generate output shifted data OSD. For example, the barrel shifter 402 is configured to receive a specific portion ISD_K (e.g., any 32-bit segment of 96-bit input data) of the intermediate shifted data ISD and perform the fine-grained circular shift operation on the specific portion ISD_K of the intermediate shifted data ISD to generate the output shifted data OSD.

Specifically, the up shifter 401 is configured to perform a segment-wise circular shift operation on the input data ID (e.g., 96-bit wide data). For example, the input data ID can be divided into a first segment SD1, a second segment SD2 and a third segment SD3, wherein each segment contains multiple bits (e.g., 32-bit wide data) of the input data ID. The up shifter 401 is configured to perform the segment-wise circular shift operation according to an up shift control signal USCS, thereby to rotate or circular shift the first segment SD1, a second segment SD2 and a third segment SD3, in a segment-wise manner (i.e., serving a 32-bit segment as a whole) to generate the intermediate shifted data ISD (e.g. 32-bit wide data).

In addition, the barrel shifters 402 is configured to perform a bit-wise circular shift operation on the specific portion of the intermediate shifted data ISD. For example, the barrel shifter 402 is configured to perform a bit-wise circular shift on the specific portion ISD_K (e.g., 32-bit wide data) of the intermediate shifted data ISD according to a barrel shift control signal BSCS_1 thereby to rotate or circular bits within the specific portion ISD_K, in a bit-wise manner to generate the output shifted data OSD.

An advantage of the hierarchical structure of the shifting circuit 400 is that the hardware implementation is mostly based on the barrel shifter 402 whose utilization is optimized for data widths that are powers of two. For example, even when the overall data block processed by the encoder 131 or decoder 132 is not a power of two (e.g., 96-bit wide in the illustrated embodiment), the hierarchical structure of the shifting circuit 400 allows t barrel shifter 402 to operate on 32-bit wide segment.

In conclusion, the hierarchical shifting circuit, in conjunction with the two-stage circulant parity-check matrix structure, preserves the error correction performance of conventional QC-LDPC codes while significantly improving hardware efficiency in barrel shifter implementations. The present invention enables high-performance LDPC encoding and decoding with reduced resource utilization, making it particularly advantageous for integration in resource-constrained or high-throughput systems.

Embodiments in accordance with the present embodiments can be implemented as an apparatus, method, or computer program product. Accordingly, the present embodiments may take the form of an entirely hardware embodiment, an entirely software embodiment, or an embodiment combining software and hardware aspects that can all generally be referred to herein as a “module” or “system.” Furthermore, the present embodiments may take the form of a computer program product embodied in any tangible medium of expression having computer-usable program code embodied in the medium. In terms of hardware, the present invention can be accomplished by applying any of the following technologies or related combinations: an individual operation logic with logic gates capable of performing logic functions according to data signals, and an application specific integrated circuit (ASIC), a programmable gate array (PGA) or a field programmable gate array (FPGA) with a suitable combinational logic.

The flowchart and block diagrams in the flow diagrams illustrate the architecture, functionality, and operation of possible implementations of systems, methods, and computer program products according to various embodiments of the present embodiments. In this regard, each block in the flowchart or block diagrams may represent a module, segment, or portion of code, which comprises one or more executable instructions for implementing the specified logical function(s). It is also noted that each block of the block diagrams and/or flowchart illustrations, and combinations of blocks in the block diagrams and/or flowchart illustrations, can be implemented by special purpose hardware-based systems that perform the specified functions or acts, or combinations of special purpose hardware and computer instructions. These computer program instructions can be stored in a computer-readable medium that directs a computer or other programmable data processing apparatus to function in a particular manner, such that the instructions stored in the computer-readable medium produce an article of manufacture including instruction means which implement the function/act specified in the flowchart and/or block diagram block or blocks.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A shifting circuit configured for performing data shifting operations associated with computation based on a two-stage circulant parity-check matrix, comprising:
an up shifter, configured to perform a coarse-grained circular shift operation on input data to generate intermediate shifted data; and
at least one first barrel shifter, configured to receive a first portion of the intermediate shifted data and perform a fine-grained circular shift operation on the first portion of the intermediate shifted data to generate first output shifted data.

2. The shifting circuit of claim 1, further comprising:
at least one second barrel shifter, configured to receive a second portion of the intermediate shifted data and perform a fine-grained circular shift operation on the second portion to generate second output shifted data.

3. The shifting circuit of claim 2, wherein the at least one first barrel shifter and the at least one second barrel shifter are configured to process data portions having a bit width equal to a power of two.

4. The shifting circuit of claim 2, wherein the at least one first barrel shifter and the at least one second barrel shifter are configured to perform a bit-wise circular shift operation on the first and second portions of the intermediate shifted data.

5. The shifting circuit of claim 1, wherein the up shifter is configured to perform a segment-wise circular shift operation on the input data.

6. The shifting circuit of claim 1, wherein the two-stage circulant parity-check matrix comprises one or more of block-circulant matrices, each of the one or more block-circulant matrix being formed by arranging a plurality of circulant permutation matrices in a circular shift manner.

7. The shifting circuit of claim 1, wherein the shifting circuit is utilized in a low-density parity-check (LDPC) encoding or decoding process based on the two-stage circulant parity-check matrix.

8. A memory controller for use in a flash memory, comprising:
a shifting circuit configured to perform data shifting operations associated with computation based on a two-stage circulant parity-check matrix, comprising:
an up shifter, configured to perform a coarse-grained circular shift operation on input data to generate intermediate shifted data; and
at least one first barrel shifter, configured to receive a first portion of the intermediate shifted data and perform a fine-grained circular shift operation on the first portion of the intermediate shifted data to generate first output shifted data.

9. The memory controller of claim 8, wherein the shifting circuit further comprises:
at least one second barrel shifter, configured to receive a second portion of the intermediate shifted data and perform a fine-grained circular shift operation on the second portion to generate second output shifted data.

10. The memory controller of claim 9, wherein the at least one first barrel shifter and the at least one second barrel shifter are configured to process data portions having a bit width equal to a power of two.

11. The memory controller of claim 9, wherein the at least one first barrel shifter and the at least on second barrel shifter are configured to perform a bit-wise circular shift operation on the first and second portions of the intermediate shifted data.

12. The memory controller of claim 8, wherein the up shifter is configured to perform a segment-wise circular shift operation on the input data.

13. The memory controller of claim 8, wherein the two-stage circulant parity-check matrix comprises one or more plurality of block-circulant matrices, each of the one or more block-circulant matrix being formed by arranging a plurality of circulant permutation matrices in a circular shift manner.

14. The memory controller of claim 8, wherein the shifting circuit is utilized in a low-density parity-check (LDPC) encoding or decoding process that is performed by the memory controller based on the two-stage circulant parity-check matrix.

15. A data storage device comprising a flash memory and the memory controller of claim 8.
